(19) United States
(12) Patent Application Publication
(10) Pub. No.: US 2026/0206605 A1
(43) Pub. Date: Jul. 16, 2026

(54) PRECISION ALIGNMENT FEATURES FOR HIGH DENSITY INTERCONNECTS

(71) Applicant: Raytheon Company, Arlington, VA (US)

(72) Inventors: Dan Booth, McKinney, TX (US); Randy L. Smith, Dallas, TX (US); Brandon W. Pillans, Plano, TX (US); Christopher Loehrlein, Murphy, TX (US); James M. Elliott, Allen, TX (US)

(21) Appl. No.: 19/025,397

(22) Filed: Jan. 16, 2025

(51) Int. Cl. H01L 23/00; H01L 23/544

(52) U.S. Cl. CPC H10W 46/00; H10W 70/60; H10W 46/301; H10W 70/09

(57) ABSTRACT

An electronics board including one or more precision alignment components including one or more layers. Each of the one or more layers includes a first planar surface and an opposing second planar surface and an alignment feature. The alignment feature can include a filled first recess defined within the one or more layers. The filled first recess can extend from the first planar surface toward the opposing second planar surface. The alignment feature can include a second recess, within the filled first recess. The second recess can extend through a fill material within the filled first recess. The fill material can be compatible with laser drilling.

### BACKGROUND

Electronics boards can include printed wiring boards (PWBs), printed circuit boards (PCBs), computer chips and layers that form the PWBs and PCBs include interconnects. Electronics boards traditionally incorporate recesses, such as holes, cavities, pockets or the like. For example, the recesses can extend through the electronics board. In another example, recesses can extend partially into the electronics board.

Recesses formed within electronics boards can include tooling holes, interconnects, or the like. Electronics boards can include recesses that can be used for aligning the electronics board relative to other components during installation or manufacturing. Recesses within electronics boards can also be used to align and couple hardware to the electronics board. Recesses, such as tooling holes can assist in the facilitation of mounting the board on different machines during manufacturing and assembly. Recesses formed within the electronics board can maintain the alignment of the electronics board during processes drilling, stencil printing, component placement in a pick-and-place machine, automated optical inspection, and testing.

### SUMMARY

A method for forming precision alignment recesses for high-density interconnects can be beneficial for forming electrical systems. For instance, electrical systems including an electronics board that has multiple components to be coupled with the board benefit from precision alignment. Precision alignment can be improved with a system that can account for alterations in the base electronics board.

In examples, the electronics board can include a first surface and an opposing second surface. The electronics board can have one or more recesses extending from the first surface toward the opposing second surface. The recess extending within the electronics board can have a width and length dimension corresponding to the surface of the electronics board. In examples, to assist with an increased precision alignment, at least one of the width or length dimensions can be increased.

To avoid having an oversized hole in the electronics board, a fill material can be deposited within the recess. Optionally, the fill material can fully fill or partially the recess. In some instances, the fill material can be compatible with laser drilling.

In some situations, the electronics board may have an altered dimension from the originally provided board and altered dimensions from the original artwork associated with the board. It can be beneficial to compare the original artwork with either the enlarged recess or with updated artwork.

When the updated recess or updated artwork can be recognized, a fiducial marker can be placed on, or relative, to a location where a new recess should be formed. For example, the fiducial marker can be placed within the circumference or area of the enlarged recess.

A new recess can be formed, such as by a laser, within the filled recess to provide for greater accuracy, or precision, in alignment of the electronics board with associated components.

### BRIEF DESCRIPTION OF THE DRAWINGS

FIG. 1 illustrates an electronics board including an enlarged recess according to at least one example of the present disclosure.

FIGS. 2A-2D illustrate an example of a method of forming a precision alignment recess according at least one example of the present disclosure.

FIGS. 3A-3D illustrates an example of a method of forming a precision alignment recess according to at least one example of the present disclosure.

FIGS. 4A-4E illustrate an example of a method of forming a precision alignment recess with a stencil according to at least one example of the present disclosure.

FIG. 5A illustrates an example of a precision alignment recess according to at least one example of the present disclosure.

FIG. 5B illustrates an example of a precision alignment recess according to at least one example of the present disclosure.

FIG. 6 illustrates an example of a precision alignment recess extending through one or more layers according to at least one example of the present disclosure.

### DETAILED DESCRIPTION

The increasing demand for high-density interconnects in modern electronic systems, particularly in radio frequency (RF) arrays, has led to challenges in achieving precise alignment of components. As system architecture unit cells become more compressed to accommodate higher frequencies, the available space for interconnects is, for example, reduced. The reduction in space can lead to tighter tolerances and higher precision throughout the architecture.

Traditional printed wiring board (PWB) manufacturing processes, that rely on mechanical drilling methods, can be limited in their ability to achieve the required positional accuracy. PWB manufacturers can, at times, achieve tooling hole drilling accuracy of ±0.002 to ±0.004 inches. At times, the precision of the placement of the tooling hole can be insufficient for high-density interconnect applications. For example, high-density interconnect applications can have much tighter tolerances than other interconnect applications.

The alignment accuracy of tooling features can be beneficial for successful implementation of advanced interconnect technologies, such as high-density pin-in-pocket assemblies. Without sufficient precision in the alignment of these tooling features, the simultaneous alignment of high-density interconnects can become challenging. In some examples, positional tolerance has become insufficient for many modern high-density interconnect applications that require much tighter tolerances.

These technical constraints and manufacturing limitations have created a significant challenge in the electronics manufacturing industry, particularly for applications requiring ultra-precise alignment of components and interconnects. Having a recess, or tooling hole, with sub-mil accuracy can be beneficial for high-density interconnects and other electronic connection assemblies.

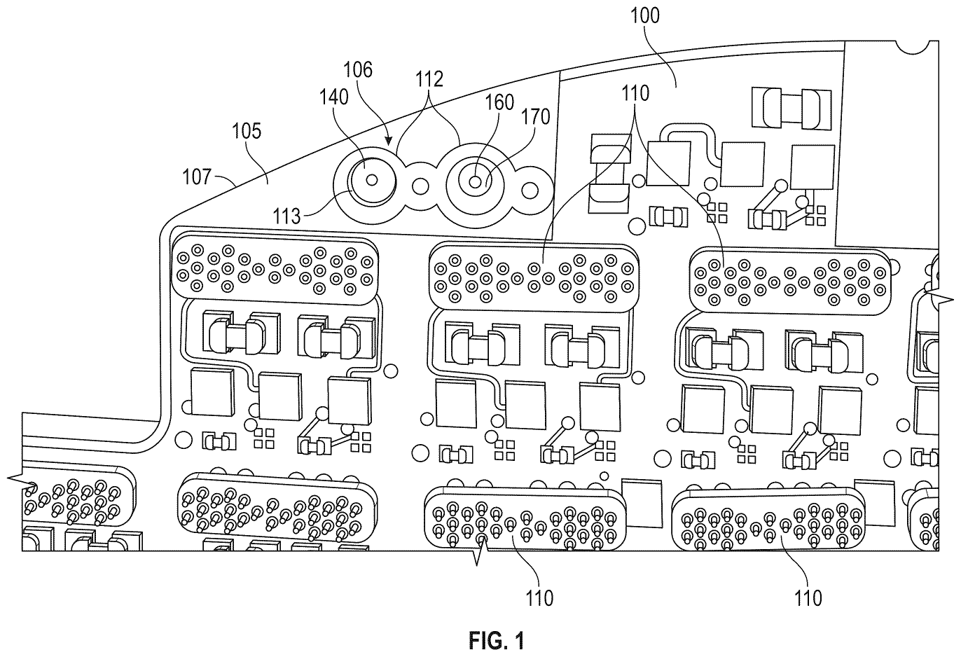

FIG. 1 illustrates an example of an electronics board 100 including a plurality of interconnects 110. The electronics board 100 can be a printed wire board (PWB) (e.g., printed circuit board or other components of a circuit or computer system), a component of an array, a computer system, an electronics system or the like. In examples, the plurality of interconnects 110 can serve as one or more pathways for electrical signals between various components mounted on the PWB. Precise placement of these interconnects can assist in ensuring optimal performance, signal integrity, and reliability of an electronic system.

In some examples, the electronics board 100 includes one or more recesses 112 defined by the electronics board. In some examples, the recesses 112 can be through-holes, through-vias, recesses, or the like that can extend through the electronics board 100. In some examples, the through-hole extends in a depth direction from a first surface 105 (as an upper surface) toward a lower surface 107 (as a bottom surface). The one or more recesses 112 can have a rounded profile, elongated profile, polygonal profile or the like. For instance, the area of the electronics board 100 surrounding the one or more recesses 112 can have a circular face 113. In another example, the area of the electronics board 100 surrounding the one or more recesses 112 can have an ovaloid, elliptical or polygonal form.

The one or more recesses 112 can be formed within the electronics board 100 proximate to an edge portion 106 of the electronics board 100. In another example, the one or more recesses 112 can be formed within the electronics board 100 more centrally within the electronics board 100. Optionally, there can be one or more recesses 112 formed within both proximate to the edge portion 106 and closer to a more central portion of the edge portion 106.

In some instances, the one or more recesses 112 can be a through-hole as a tooling hole. Tooling holes on a (PWB) can be precisely positioned holes or recesses. Tooling holes can be used for alignment and registration purposes during manufacturing and assembly processes. Tooling holes can assist in maintaining accurate alignment of the PWB with various manufacturing equipment, such as drilling machines, pick-and-place machines, and automated optical inspection systems. In some examples, this alignment can be important for maintaining the positional accuracy of components and interconnects on the board. In other examples, such as with multi-layer fabrication of PWBs, tooling holes can assist in aligning and registering the different layers accurately. Proper alignment can ensure conductive traces and vias on each layer can be correctly positioned relative to one another.

In the example illustrated in FIG. 1, there can be two recesses of the one or more recesses 112. One recess of the one or more recesses 112 can be an initial recess 140. An initial recess 140 can include a recess (e.g., through-hole, through via, cavity or the like) formed with the electronics board 100. The other recess of the one or more recesses 112 illustrated in FIG. 1 can be an enlarged recess 160. The enlarged recess 160 can includes a recess that, for example, has been subjected to additional manufacturing processes.

The additional manufacturing processes can include enlarging or expanding the dimensions of the at least one of the one or more recesses 112. Enlarging the recess can include increasing at least one dimension of the recess. For instance, at least one or more of the width of the recess or length of the recess, relative to the first surface 105.

The enlarged recess 160 can, for example, be filled with a fill material 170. The fill material 170 can assist in ensuring there are not any unnecessary openings, holes, cavities, or the like in the electronics board 100. In other examples, the fill material 170 can be subjected to further mechanical processes to form a new recess (e.g., through-hole, through via, cavity or the like).

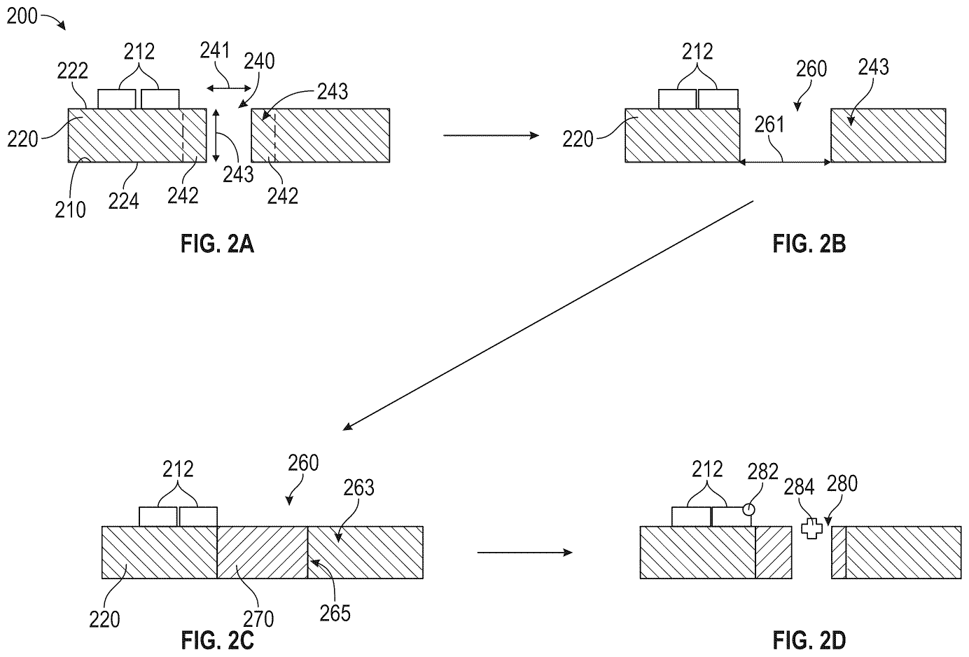

FIG. 2A illustrates an example of a method 200 of forming a precision alignment recess. In examples, an electronics board 210 can be formed from one or more layers 220. The one or more layers 220 can be formed to support one or more components 212. The one or more components 212 can include interconnects such as high-density interconnects. The one or more components 212 can include pin-in-pocket interconnects that can require precision and accuracy for proper alignment. The one or more components 212 can also include other components, such as radio frequency (RF) connectors, resistors, capacitors, memory units, or the like.

The electronics board 210 can be manufactured or formed with one or more recesses 240 (e.g., through-hole, through via, cavity or the like) extending from a first planar surface 222 toward a second planar surface 224. The one or more recesses 240 can extend from the first planar surface 222 and through the electronics board 210 to the second planar surface 224. The one or more recesses 240 formed within the electronics board 210 can be a through-hole or through-via. The area of the electronics board 210 surrounding the one or more recesses 240 can have a base dimension 241 having width dimension and a length dimension relative to the first planar surface 222 or the second planar surface 224 that defines an opening of the one or more recesses 240. For example, the one or more recesses 240 can have a diameter or radius as the length or width. In some examples, the area of the electronics board 210 that defines the one or more recesses 240 can have a substantially circular or elliptical profile. In another example, the area of the electronics board 210 that defines the one or more recesses 240 can have at least a portion having a circular or rounded profile and other portions can be linear. Optionally, the one or more recesses 240 can be a slot or a cylindrical hole.

Optionally, the one or more recesses 240 are formed within the electronics board having an initial dimension. The initial dimension can be the base dimension 241 having a first width or a first length. In some examples, the one or more recesses 240 can be extended to have an increased base dimension 241. For instance, a predetermined amount 242 of material of the electronics board 210 proximate to a perimeter of the one or more recesses 240 can be removed. The predetermined amount 242 of the one or more recesses 240 can be removed by etching, grinding, or other mechanical or chemical methods.

Illustrated in FIG. 2B can be an example of the electronics board 210 that can define an enlarged recess 260. The enlarged recess 260 can have an increased base dimension 261 as compared to the base dimension 241 of the one or more recesses 240 in an initial configuration. For example, the distance from one upper edge portion 263 to an opposing upper edge portion 263 can be increased relative to the distance between upper edge portions 243 before enlargement. The increased base dimension 261 can have an increased width dimension or an increased length dimension as compared to the base dimension 241 in the initial configuration. Increasing the base dimension 241 to the increased base dimension 261 can allow for a greater area to account for possible misalignments when components or additional layers are coupled with the electronics board 210.

In example, cavities or the like, the enlarged recess 260 can be filled with a fill material 270 to minimize or unintentionally form openings in the electronics board 210. The fill material 270 can be deposited or filled in the enlarged recess 260. The fill material 270 can fill the enlarged recess 260 from proximate to a lower region 265 to proximate to an upper edge portion 263 of the electronics board 210. For example, the fill material 270 can be filled proximate to the lower region 265 so the second planar surface 224 can be continuous over the area where enlarged recess 260 was formed. In another example, the fill material 270 can be filled so there is space between the fill material 270 and the second planar surface 224. For instance, the fill material 270 can be filled to be discontinuous with the second planar surface 224. The fill material 270 can be filled through the enlarged recess 260 until the fill material 270 can be approximately level (e.g., forming a continuous surface with the first planar surface 222) with the first planar surface 222. In an example, the fill material 270 can be filled a predetermined amount such that the fill material 270 can be removed from the first planar surface 222. For instance, the fill material 270 can form a cavity (e.g., indentation, depression or the like) relative to the first planar surface 222.

The fill material 270 can be formed from a material that solidifies when set or cooled. In an example, the fill material 270 can be formed from a material that can be compatible with laser drilling. The fill material 270 can withstand the energy from a laser beam while being compliant with the laser beam forming a recess through the fill material 270. In an example, the fill material 270 can include an adhesive, epoxy or the like.

The second recess 280 can be formed within the fill material 270 according to a predetermined location. The predetermined location can be determined relative to one or more locations of the one or more components 212, an edge portion of the one or more layers 220 or the electronics board 210, a portion of the one or more recesses 240 or the enlarged recess 260. The predetermined location can be correlated with one or more reference points 282 on the electronics board 210. The one or more components 212 or other structural portion of the electronics board 210 can be the one or more reference points 282.

The one or more reference points 282 can be correlated with an artwork plan associated with the electronics board 210. The one or more reference points 282 can be correlated with the artwork plan of the electronics board 210 that were prepared with the original electronics board 210. The one or more reference points 282 can be correlated with an updated artwork plan of the electronics board 210. For instance, the updated artwork plan can be prepared after a manufacturing process can be performed related to the electronics board 210. The updated artwork plan can be prepared after components have been coupled with the electronics board 210 or additional layers of the one or more layers 220 have been coupled together.

The updated artwork can be prepared based on measurements taken of the electronics board 210 or the one or more layers 220 after a manufacturing process has been performed. The updated artwork can be prepared according to sensed properties (e.g., component location, layer, or board geography or the like) by one or more optical systems. The one or more optical system can be in communication with a control system (e.g., processor, computer or the like). The control system can have access to data related to the original artwork. In examples, the control system can compare the original artwork with the measured artwork.

The comparison of the original artwork with the measured artwork can provide a more accurate location for the second recess 280. For example, the comparison of the original artwork with the measured artwork can assist with the control system in identifying a location for the second recess 280. In some examples, the location of the second recess 280 can be off-center from the enlarged recess 260. In another example, the location of the second recess 280 can be closer to an edge portion of the enlarged recess 260 than to a central portion. The enlarged recess 260 can account for deviations in the dimensions of the electronics board 210 or the one or more layers 220. The filled, enlarged recess 260 can accommodate new locations for the second recess 280 than originally contemplated when the PWB was formed.

In an example, a fiducial marker 284 can be selected based on one or more reference points 282. The fiducial marker 284 can be positioned on or relative to the fill material 270 according to a characteristic of the measured artwork or updated geometry of the artwork. The fiducial marker 284 can be positioned with a higher degree of accuracy, such as within approximately ±0.05 mils (approximately 0.0005 inches or approximately 12.5 microns) and approximately 0.03 mils (approximately 0.0003 inches or approximately 7.5 microns). The comparison of the original artwork with the measured artwork, or using the measured artwork alone, can assist in more precisely locating a fiducial marker within tolerance magnitudes lower than approximately 0.03 mils (approximately 0.0003 inches or approximately 7.5 microns).

The second recess 280 can be formed within the fill material 270, for example with laser drilling, according to the fiducial marker aligned according to the comparison between the original artwork and the measured artwork. Optionally, the second recess 280 can be formed according to the fiducial marker aligned according to the measured artwork. A second recess 280, as a precision alignment recess, can be formed within the fill material 270 according to the fiducial marker 284. The second recess 280 can be formed to extend through the fill material 270. The second recess 280 can be a through-hole or through-via. The second recess 280 can be a tooling hole. For example, the second recess 280 can be formed at a lateral location within the fill material 270. The second recess 280 can be formed so it can be closer to one side of the second recess 280 than another side. The second recess 280 can be formed so it can be centrally positioned within the second recess 280.

The second recess 280 can be formed within the fill material 270 with drilling, laser drilling, punching, or other mechanical process. Optionally, laser drilling forms the second recess 280 as a second through-hole. During a laser drilling process, a laser beam can remove material from a specified area. Laser drilling can form recesses or holes of many different sizes, shapes or profiles according to the purpose.

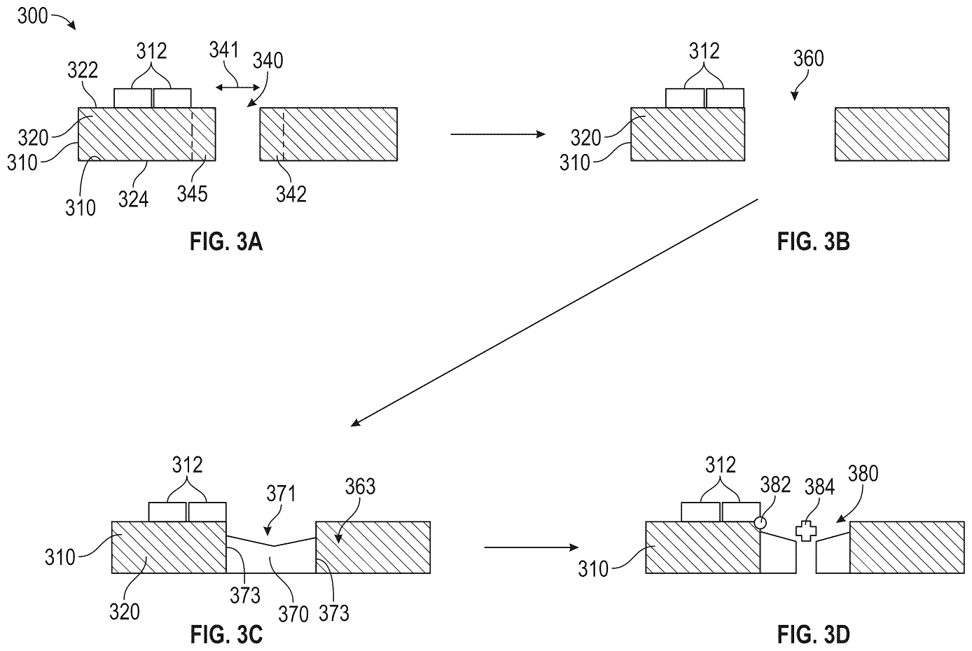

FIGS. 3A through 3D illustrate a method 300 for forming a second recess 380, as a through hole, within a fill material 370. The processes illustrated in FIGS. 3A and 3B can be similar to the processes illustrated in FIGS. 2A and 2B. For example, an original, or first, recess 340 can be formed within an electronics board 310 or a layer 320. The recess 340 can be defined by one or more walls 345 that extend through the electronics board 310 from a first planar surface 322 to a second planar surface 324 and surround the recess 340. The area of the electronics board 310 surrounding recess 340 can have a base dimension 341 having a first width or length and a first depth. For example, the base dimension 341 of the area of the electronics board 310 around the recess 340 can have a rounded, circular, elliptical, or elongated form.

The base dimension 341 (e.g., the dimension between portions of the layer 320) of the recess 340 can be expanded a predetermined amount 342 by removing material within the recess 340. Removing the predetermined amount 342 of material can form an expanded or enlarged recess 360 (e.g., increasing the space between portions of the layer 320 defining the recess).

In the example illustrated in FIG. 3C, the expanded or enlarged recess 360 can be filled with a fill material 370. The fill material 370 can be filled to have a tapered profile 371. The tapered profile 371 can have an inward taper from an upper edge region 363 of the electronics board 310 defining the recess toward a central portion of the recess. The tapered profile 371 can taper from a portion of a wall 373 defining the recess that can be removed a predetermined distance from a first planar surface 322 of the layer 320. The tapered profile 371 can have a substantially conical form or a truncated conical form. The tapered profile 371 can account for the form of a laser beam used during a laser drilling process.

After fill material 370 has been deposited in the predetermined form (e.g., with an inwardly tapering profile), original artwork related to the electronics board 310 can be referenced by a control system (e.g., computer, processor or the like). The referenced original artwork can be updated to account for any alterations in the geometry of the electronics board 310. The referenced original artwork can also be updated to account for alterations in the positions of components 312 coupled with the electronics board 310. In another example, the control system can prepare artwork related to the form of the electronics board 310 without referencing original artwork related to the electronics board 310.

A position of a fiducial marker 384 can be selected according to the location of one or more reference points 382. For example, one reference point of the one or more reference points 382 can be selected based on a portion of a component 312 positioned on the electronics board 310. The one or more reference points 382 can also be selected based on a portion of the geometry of the electronics board 310. In an example, one or more fiducial marker 384 is positioned based on the location of the one or more reference points 382.

Illustrated in FIG. 3D can be an example of forming a second recess 380 defined by the fill material 370. The second recess 380 can be formed with laser drilling at or proximate to the fiducial marker 384. In an example, a fiducial marker 284 can be positioned on or relative to the fill material 370 according to a characteristic of at least one of the measured artwork, updated geometry of the artwork or form of the fill material 370. The fiducial marker 384 can be positioned with a higher degree of accuracy, such as within approximately ±0.05 mils (approximately 0.0005 inches or approximately 12.5 microns) and approximately 0.03 mils (approximately 0.0003 inches or approximately 7.5 microns). The comparison of the original artwork with the measured artwork, or using the measured artwork alone, can assist in more precisely locating a fiducial marker within tolerance magnitudes lower than approximately 0.03 mils (approximately 0.0003 inches or approximately 7.5 microns).

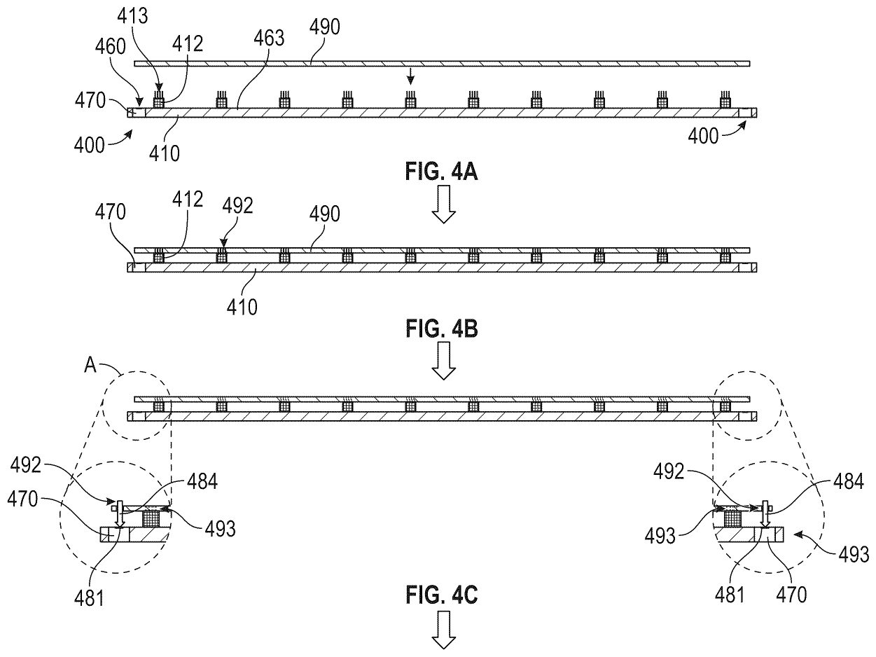

FIGS. 4A-4E illustrate a method for forming a precision alignment feature 400 in an electronics board 410. The precision alignment feature 400 can be formed similar to the methods described previously related to FIG. 2A-2D or 3A-3D. For example, as illustrated in FIG. 4A, the precision alignment feature 400 includes a one or more enlarged recesses 460 including a fill material 470. The method of FIGS. 4A-4E can include a stencil 490. The stencil 490 can include varying pin holes 493 (e.g., recesses, cavities, indentations or the like) having diameters associated with pins 413 of one or more components 412 on the electronics board 410. For instance, the one or more components 412 can include pinned components, such as pins for pin-in-pocket interconnects. The stencil 490 including varying pin holes 493 corresponding to the size or dimensions of the pins 413 can be aligned relative to the electronics board 410. A stencil 490 having holes that can correspond in size or dimension to the pins 413 can establish proper positioning of the stencil 490 relative to the electronics board 410.

One or more alignment recesses 492 can be formed within the 490. The one or more alignment recesses 492 can be formed to correspond to a targeted location of the fill material 470 in the one or more enlarged recesses 460. For example, the one or more enlarged recesses 460 can be a tooling hole as described previously.

Illustrated in FIG. 4B, the stencil 490 can be positioned relative to the electronics board 410. The stencil 490 can be positioned with each of the varying pin holes 493 aligned with the pins 413 of the one or more components 412. In some examples, the stencil 490 can be positioned over all or the majority of the pins 413. The stencil 490 in other examples can cover the pins 413. For instance, the stencil 490 can be at least partially in contact with at least one of the one or more components 412 when aligned with the electronics board 410. Aligning the stencil 490 with the varying pin holes 493 over the pins 413 can position the one or more alignment recesses 492 in a precise position relative to the one or more enlarged recesses 460 including the fill material 470.

As illustrated in FIG. 4C, the stencil 490 can be positioned with the varying pin holes 493 coupled with the pins 413. The stencil 490 can also be positioned with the one or more alignment recesses 492 positioned relative to the fill material 470 of the one or more enlarged recesses 460. An alignment marker 481 (e.g., reference marker) can be printed on the fill material 470 when the stencil 490 is coupled with the varying pin holes 493. For example, a laser beam 484 can be emitted to pass through the one or more alignment recesses 492 of the stencil 490. The laser beam 484 can print or otherwise imprint an alignment marker 481 at or proximate to a location where a tooling hole can be formed within the fill material 470. The laser beam 484 can be used to print alignment marker 481 in more than one location according to the number of one or more alignment recesses 492 formed in the stencil 490. A subsequent laser beam 485 can form a second recess 480 in the fill material 470.

FIG. 4D illustrates an example with the stencil 490 removed after the alignment marker 481 has been printed, or otherwise marked, on the fill material 470. A subsequent laser beam 485 can be emitted towards the alignment marker 481. The subsequent laser beam 485 can form the second recess 480 in the fill material 470. The second recess 480 can extend through the fill material 470 from proximate to an upper edge region 463 of the electronics board 410 to proximate to a lower edge region 465 of the electronics board 410. In another example, the second recess 480 can extend only partially within the fill material 470.

FIG. 4E illustrates an example of base guide 495 positioned relative to the electronics board 410. The base guide 495 can include one or more alignment pins 496 extending away from a surface of the base guide 495. For instance, the one or more alignment pins 496 can extend in a direction away from the 495 so the electronics board 410 can be removably coupled with the base guide 495. The one or more alignment pins 496 can be formed on the base guide 495 according to predetermined locations for use.

The electronics board 410 can be removably coupled with the base guide 495 and the one or more alignment pins 496 can extend through the second recess 480 formed in the fill material 470. To confirm proper alignment, the stencil 490 can be repositioned relative to the one or more components 412 and the pins 413 to confirm proper alignment of each of the pins 413 and the second recess 480. The base guide 495 can verify precision alignment of the precision alignment feature 400.

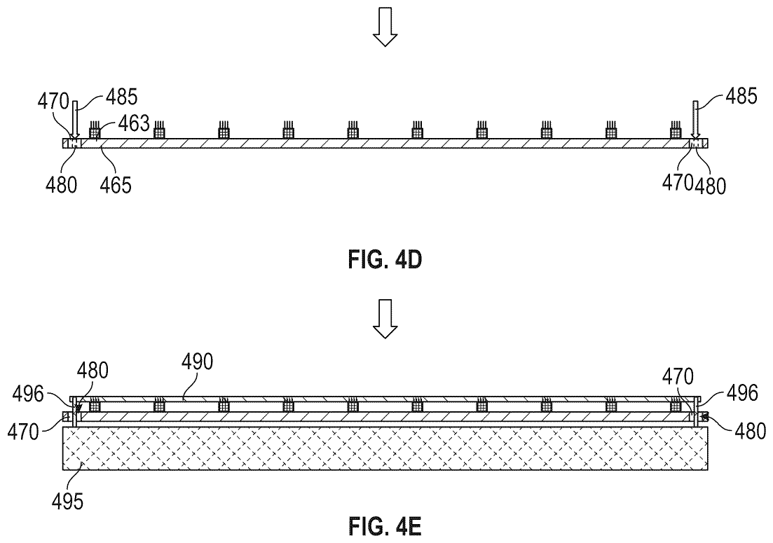

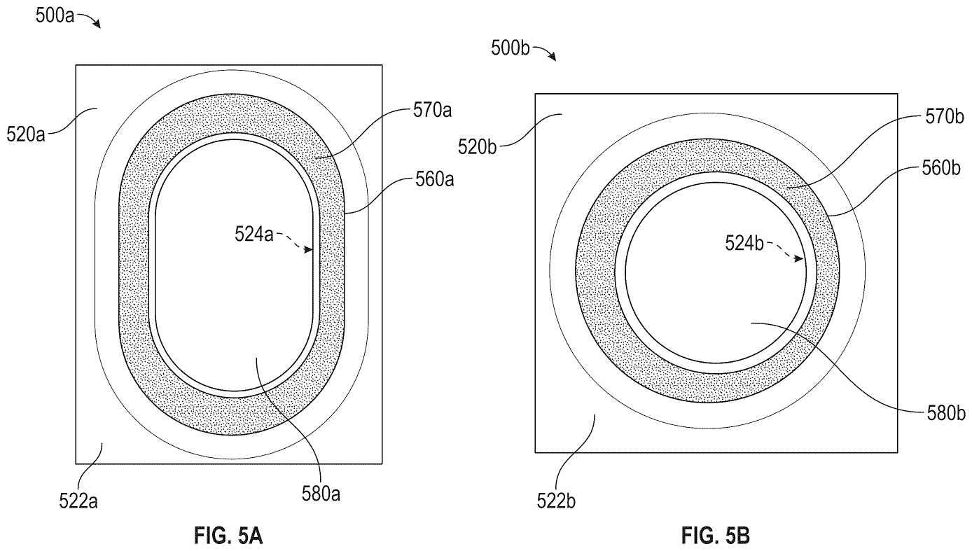

Illustrated in FIG. 5A is an example of an alignment feature 500a that can include a filled, enlarged recess 560a with a second recess 580a extending through a layer 520a. As illustrated in FIG. 5A, the recess 560a can be formed by removing material from an original recess. Fill material 570a can be deposited or filled into the recess 560a. A second recess 580a can be formed within the fill material 570a. For example, the second recess 580a can be formed and defined by the fill material 570a. The second recess 580a can extend through the layer 520a from, for example, a first planar surface 522a toward a second planar surface 524a.

The alignment feature 500a can have a rounded form, such as an elliptical form or an oval form. For example, fill material 570a can have an oval form, or a combination of curved and linear forms extending around the second recess 580a. The alignment feature 500a can be a through-hole, through-via or a tooling hole positioned to extend through the layer 520a. In an example, the alignment feature 500a can be a slot that can be positioned within a portion of the layer 520a.

Illustrated in FIG. 5B can be an example of an alignment feature 500b that can include a filled, enlarged recess 560b with a second recess 580b extending through a layer 520b. As illustrated in FIG. 5B, the recess 560b can be formed by removing material from an original recess. Fill material 570b can be deposited or filled into the recess 560b. A second recess 580b can be formed within the fill material 570b. For example, the second recess 580b can be formed and defined by the fill material 570b and can extend through the layer 520b from, for example, a first planar surface 522b toward a second planar surface 524b.

The alignment feature 500b can have a rounded form, such as a circle. For example, fill material 570b can have a substantially circular profile relative to the first planar surface 522b. The alignment feature 500b can be a through-hole, through-via or a tooling hole positioned to extend through the layer 520b. In an example, the alignment feature 500b can be a through-hole that can be positioned within a portion of the layer 520b.

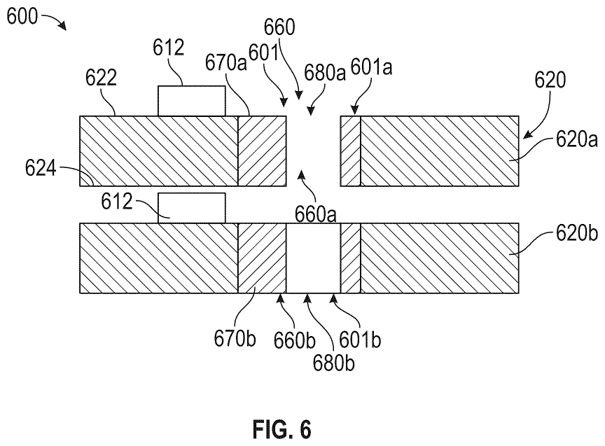

Illustrated in FIG. 6 can be an example of an electronics device 600 including one or more alignment features 601. The electronics device 600 can include one or more electronics boards 620. The one or more electronics boards 620 can include one or more layers, substrates, PWBs or the like that can form the electronics device 600 that can benefit from the one or more alignment features 601.

In the example illustrated two electronics boards 620 can be positioned relative to each other. For example, a first electronics board 620a and a second electronics board 620b can be positioned are stacked. Each of the first electronics board 620a and the second electronics board 620b can include one or more electrical components 612. The first electronics board 620a can include a first alignment feature 601a. The first alignment feature 601a can be similar to the alignment features discussed related to FIGS. 2A-4B. The second electronics board 620b can include a second alignment feature 601b. The second alignment feature 601b can be similar to the alignment features discussed related to FIGS. 2A-4B.

In an example, one or more of the first electronics board 620a and second electronics board 620b can include a first alignment feature 601a and second alignment feature 601b, respectively that each can include a filled recess 660. Each of the first alignment feature 601a and the second alignment feature 601b can include a filled recess 660 defined by the one or more electronics boards 620. For instance, the one or more filled recess 660 can be formed to extend within the one or more electronics boards 620 from a first planar surface 622 to a second planar surface 624.

The one or more filled recess 660 can be filled with a fill material 670a, 670b. For example, the first electronics board 620a can include a first filled recess 660a including a first fill material 670a. The second electronics board 620b can include a second filled recess 660b including a second fill material 670b. The second fill material 670b can be the same, similar, or different from the first fill material 670a. In an example, at least one of the first fill material 670a and the second fill material 670b are compatible with laser drilling. The first fill material 670a and the second fill material 670b can be one or more of an epoxy that can be compatible with laser drilling.

The first electronics board 620a and the second electronics board 620b can be aligned with each other. In examples, the first electronics board 620a and the second electronics board 620b can be stacked with the first filled recess 660a and the second filled recess 660b aligned with each other. The first filled recess 660a and the second filled recess 660b can be aligned with each other with the first recess 680a and the second recess 680b aligned with each other.

The aligned first electronics board 620a and second electronics board 620b can form an electronics device 600, such as a PWB or a component of a PWB. The first electronics board 620a and the second electronics board 620b can form a component of a radio frequency array. Optionally, the electronics device 600 can be a component of a larger electrical device such as a radar, aerospace, or terrestrial device.

### Aspects

Aspect 1 can include subject matter such as method for forming precision alignment recesses for high-density interconnects, comprising: providing an electronics board, the electronics board including: a first surface and an opposing second surface; and one or more recesses extending from the first surface toward the opposing second surface; wherein the one or more recesses include a width dimension and length dimension relative to the first surface of the electronics board and a depth dimension extending from the first surface toward the opposing second surface; increasing one or more of the width dimension or length dimension of the one or more recesses; depositing fill material in the one or more recesses; selecting one or more reference points on the electronics board; selecting a position of one or more fiducial markers based on the one or more reference points; and laser drilling a second through-hole through the fill material at a lateral location within the fill material that is correlated to the fiducial marker.

Aspect 2 can include, or can optionally be combined with the subject matter of Aspect 1, to optionally include including positioning a stencil relative to the electronics board; wherein the stencil includes one or more alignment recesses; and emitting a laser beam through the one or more alignment recesses to form the second through-hole.

Aspect 3 can include, or can optionally be combined with the subject matter of one or any combination of Aspects 1 or 2 to optionally include the one or more reference points includes one or more edge of an electrical component coupled with the electronics board.

Aspect 4 can include, or can optionally be combined with the subject matter of one or any combination of Aspects 1 to 3 to optionally include the one or more recesses is a through-hole having one of a rounded profile, circular profile, or elliptical profile.

Aspect 5 can include, or can optionally be combined with the subject matter of one or any combination of Aspects 1 to 4 to optionally include the one or more recesses is a tooling hole.

Aspect 6 can include, or can optionally be combined with the subject matter of one or any combination of Aspects 1 to 5 to optionally include the lateral location correlates to at least one difference between artwork plan and measured electronics board.

Aspect 7 can include, or can optionally be combined with the subject matter of one or any combination of Aspects 1 to 6 to optionally include the at least one difference is related to shrinkage of the electronics board.

Aspect 8 can include, or can optionally be combined with the subject matter of one or any combination of Aspects 1 to 7 to optionally include forming the one or more recesses to have a positional tolerance of 0.0003 mils.

Aspect 9 can include, or can optionally be combined with the subject matter of one or any combination of Aspects 1 to 8 to optionally include filling the one or more recesses includes depositing the fill material into each recess of the one or more recesses to have an inward taper.

Aspect 10 can include, or can optionally be combined with the subject matter of one or any combination of Aspects 1 to 9 to optionally include depositing the fill material includes partially filling the one or more recesses with the fill material.

Aspect 11 can include, or can optionally be combined with the subject matter of one or any combination of Aspects 1 to 10 to optionally include the fill material includes an epoxy.

Aspect 12 can include subject matter such as an electronics board including one or more precision alignment components, the electronics board comprising: one or more layers including: a first planar surface and an opposing second planar surface; and an alignment feature, including: a filled first recess defined within the one or more layers, the recess configured to extend from the first planar surface toward the opposing second planar surface; a second recess, within the filled first recess, the second recess extending through a fill material within the filled first recess, the fill material being compatible with laser drilling.

Aspect 13 can include, or can optionally be combined with the subject matter of Aspect 12, to optionally include the fill material includes one of an adhesive or an epoxy.

Aspect 14 can include, or can optionally be combined with the subject matter of one or any combination of Aspects 12 or 13 to optionally include the filled first recess has a rounded profile.

Aspect 15 can include, or can optionally be combined with the subject matter of one or any combination of Aspects 12 to 14 to optionally include the filled first recess is positioned proximate to an edge region of the electronics board.

Aspect 16 can include, or can optionally be combined with the subject matter of one or any combination of Aspects 12 to 15 to optionally include in the fill material has a tapered profile; wherein the tapered profile is inwardly tapered towards a central portion of the recess from an edge portion of the recess.

Aspect 17 can include, or can optionally be combined with the subject matter of one or any combination of Aspects 12 to 16 to optionally include the electronics board can be a printed wire board.

Aspect 18 can include subject matter such as an electronics device including one or more precision alignment components, the electronics board system comprising: a first board with a first alignment feature, the first alignment feature including: a first filled recess located laterally in a first offset and defined within the first board, the recess configured to extend from a first planar surface of the first board toward an opposing second planar surface of the first board; a first recess, within the first filled recess, the first recess extending through a fill material within the first filled recess, the fill material being compatible with laser drilling; a second board with a second alignment feature, the second alignment feature including: a second filled recess located laterally in a second offset, different from the first offset, of the second board and defined within the second board; a second recess, within the second filled recess, the second recess extending through a fill material within the second filled recess, the fill material being compatible with laser drilling; and the first alignment feature and second alignment feature aligned together.

Aspect 19 can include, or can optionally be combined with the subject matter of Aspect 18, to optionally include at least two layers of the one or more layers; wherein the first board and the second board are stacked; wherein the electronics board system can be a component of a radio frequency array.

Aspect 20 can include, or can optionally be combined with the subject matter of one or any combination of Aspects 18 or 20 to optionally include the fill material disposed within the recess has a tapered profile; wherein the fill material tapers from proximate to an edge portion of the recess toward a central portion of the recess.

In the event of inconsistent usages between this document and any documents so incorporated by reference, the usage in this document controls.

In this document, the terms “a” or “an” are used, as can be common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel,” “perpendicular,” “round,” or “square,” are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

The above description is intended to be illustrative, and not restrictive. For example, the above-described aspects or examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, subject matter may lie in less than all features of a particular disclosed embodiment. Thus, the following claims are hereby incorporated into the Detailed Description as aspects, examples, or embodiments, with each claim standing on its own as a separate embodiment, and it is contemplated that such embodiments can be combined with each other in various combinations or permutations. The scope of the disclosed concepts should be determined with reference to the appended claims, along with the full scope of equivalents to which such claims are entitled.

What is claimed is:

1. A method for forming precision alignment recesses for high-density interconnects, comprising:
providing an electronics board, the electronics board including:
a first surface and an opposing second surface; and
one or more recesses extending from the first surface toward the opposing second surface;
wherein the one or more recesses include a width dimension and length dimension relative to the first surface of the electronics board and a depth dimension extending from the first surface toward the opposing second surface;
increasing one or more of the width dimension or length dimension of the one or more recesses;
depositing fill material in the one or more recesses;
selecting one or more reference points on the electronics board;
selecting a position of one or more fiducial markers based on the one or more reference points; and
laser drilling a second through-hole through the fill material at a lateral location within the fill material that is correlated to the fiducial marker.

2. The method for forming the precision alignment recesses of claim 1, including positioning a stencil relative to the electronics board;
wherein the stencil includes one or more alignment recesses; and
emitting a laser beam through the one or more alignment recesses to form the second through-hole.

3. The method for forming the precision alignment recesses of claim 1, wherein the one or more reference points includes one or more edge of an electrical component coupled with the electronics board.

4. The method for forming the precision alignment recesses of claim 1 wherein, the one or more recesses is a through-hole having one of a rounded profile, circular profile, or elliptical profile.

5. The method for forming the precision alignment recesses of claim 1, wherein the one or more recesses is a tooling hole.

6. The method for forming the precision alignment recesses of claim 1, wherein the lateral location correlates to at least one difference between artwork plan and measured electronics board.

7. The method for forming the precision alignment recesses of claim 1, wherein selecting a reference point is based on shrinkage of the electronics board.

8. The method for forming the precision alignment recesses of claim 1, including:
forming the one or more recesses to have a positional tolerance of 0.0003 mils.

9. The method for forming the precision alignment recesses of claim 1, wherein filling the one or more recesses includes depositing the fill material into each recess of the one or more recesses to have an inward taper.

10. The method for forming the precision alignment recesses of claim 1, wherein depositing the fill material includes partially filling the one or more recesses with the fill material.

11. The method for forming the precision alignment recesses of claim 1, wherein the fill material includes an epoxy.

12. An electronics board including one or more precision alignment components, the electronics board comprising:
one or more layers including:
a first planar surface and an opposing second planar surface; and
an alignment feature, including:
a filled first recess defined within the one or more layers, the recess configured to extend from the first planar surface toward the opposing second planar surface; and
a second recess, within the filled first recess, the second recess extending through a fill material within the filled first recess, the fill material being compatible with laser drilling.

13. The electronics board of claim 12, wherein the fill material includes one of an adhesive or an epoxy.

14. The electronics board of claim 12, wherein the filled first recess has a rounded profile.

15. The electronics board of claim 12, wherein the filled first recess is positioned proximate to an edge region of the electronics board.

16. The electronics board of claim 12, wherein in the fill material has a tapered profile;
wherein the tapered profile is inwardly tapered towards a central portion of the recess from an edge portion of the recess.

17. The electronics board of claim 12, wherein the electronics board is a printed wire board.

18. An electronics device including one or more precision alignment components, the electronics device comprising:
a first board with a first alignment feature, the first alignment feature including:
a first filled recess located laterally in a first offset and defined within the first board, the recess configured to extend from a first planar surface of the first board toward an opposing second planar surface of the first board; and
a first recess, within the first filled recess, the first recess extending through a fill material within the first filled recess, the fill material being compatible with laser drilling;
a second board with a second alignment feature, the second alignment feature including:
a second filled recess located laterally in a second offset, different from the first offset, of the second board and defined within the second board; and
a second recess, within the second filled recess, the second recess extending through a fill material within the second filled recess, the fill material being compatible with laser drilling; and
the first alignment feature and second alignment feature aligned together.

19. The electronics device of claim 18, wherein the first board and the second board are stacked;
wherein the electronics device is a component of a radio frequency array.

20. The electronics device of claim 18, wherein the fill material disposed within the recess has a tapered profile;
wherein the fill material tapers from proximate to an edge portion of the recess toward a central portion of the recess.
